(19) United States
(12) Patent Application Publication
(10) Pub. No.: US 2025/0102907 A1
(43) Pub. Date: Mar. 27, 2025

(54) SEMICONDUCTOR PHOTORESIST COMPOSITION AND METHOD OF FORMING PATTERNS USING THE COMPOSITION

(71) Applicant: SAMSUNG SDI CO., LTD., Yongin-si (KR)

(72) Inventors: Minyoung LEE, Suwon-si (KR); Jimin KIM, Suwon-si (KR); Wanhee LIM, Suwon-si (KR); Jun SAKONG, Suwon-si (KR); Minki CHON, Suwon-si (KR); Changsoo WOO, Suwon-si (KR); Seung-Wook SHIN, Suwon-si (KR)

(21) Appl. No.: 18/676,313

(22) Filed: May 28, 2024

(30) Foreign Application Priority Data
Jul. 21, 2023 (KR) 10-2023-0095526

(51) Int. Cl. G03F 7/004; H01L 21/027

(52) U.S. Cl. CPC G03F 7/0042; H01L 21/0274

(57) ABSTRACT

Disclosed are a semiconductor photoresist composition including an organometallic compound; a vinyl group-containing acid compound; and a solvent, and a method of forming a pattern using the same.

### CROSS-REFERENCE TO RELATED APPLICATION

The present application claims priority to and the benefit of Korean Patent Application No. 10-2023-0095526 filed on Jul. 21, 2023, in the Korean Intellectual Property Office, the entire content of which is hereby incorporated herein by reference.

### BACKGROUND

### 1. Field

Embodiments of this disclosure relate to a semiconductor photoresist composition and a method of forming patterns using the same.

### 2. Description of the Related Art

EUV (extreme ultraviolet) lithography is paid attention to as one technology for manufacturing a next generation semiconductor device. EUV lithography is a pattern-forming technology using an EUV ray having a wavelength of 13.5 nm as an exposure light source. According to EUV lithography, an extremely fine pattern (e.g., less than or equal to 20 nm) may be formed in an exposure process during a manufacture of a semiconductor device.

Extreme ultraviolet (EUV) lithography is realized through development of compatible photoresists which can be performed at a spatial resolution of less than or equal to 16 nm. Currently, efforts to satisfy insufficient specifications of traditional chemically amplified (CA) photoresists such as a resolution, a photospeed, and feature roughness (also referred to as a line edge roughness or LER) for next generation devices are being made.

An intrinsic image blurring due to an acid catalyzed reaction in these polymer-type photoresists limits a resolution in small feature sizes, which has been present in electron beam (e-beam) lithography for a long time. The chemically amplified (CA) photoresists are designed for high sensitivity, but because their general elemental makeups reduce light absorbance of the photoresists at a wavelength of 13.5 nm and thus decrease their sensitivity, the chemically amplified (CA) photoresists may partially have more difficulties under an EUV exposure.

the CA photoresists may have difficulties in the small feature sizes due to roughness issues, and line edge roughness (LER) of the CA photoresists experimentally turns out to be increased, as a photospeed is decreased partially due to an essence of acid catalyst processes. Accordingly, a high-performance photoresist would be beneficial in a semiconductor industry because of these defects and problems of the CA photoresists.

In order to overcome the aforementioned drawbacks of the chemically amplified (CA) organic photosensitive composition, an inorganic photosensitive composition has been researched. The inorganic photosensitive composition is mainly used for negative tone patterning having resistance against removal by a developer composition due to chemical modification through a nonchemical amplification mechanism. The inorganic composition contains an inorganic element having a higher EUV absorption rate than hydrocarbon and thus may secure sensitivity through the nonchemical amplification mechanism and in addition, is less sensitive with respect to a stochastic effect and thus has a low line edge roughness and a small number of defects.

Inorganic photoresists based on peroxopolyacids of tungsten mixed together with tungsten, niobium, titanium, and/or tantalum have been developed as radiation sensitive materials for patterning.

These materials are effective for patterning large pitches for bilayer configuration for far ultraviolet (deep UV), X-ray, and electron beam sources. More recently, when cationic hafnium metal oxide sulfate (HfSOx) materials along with a peroxo complexing agent has been used to image a 15 nm half-pitch (HP) through projection EUV exposure, impressive performance has been obtained. This system exhibits the highest performance of a non-CA photoresist and has a practicable photospeed near to level useful for an EUV photoresist. However, the hafnium metal oxide sulfate material having the peroxo complexing agent has a few practical drawbacks. First, these materials are coated in a mixture of corrosive sulfuric acid/hydrogen peroxide and have insufficient shelf-life stability. Second, a structural change thereof for performance improvement as a composite mixture is not easy. Third, development should be performed in a TMAH (tetramethylammonium hydroxide) solution at an extremely high concentration of 25 wt % and/or the like.

Recently, active research has been conducted considering that molecules containing tin have excellent absorption of extreme ultraviolet rays. As for an organotin polymer among them, alkyl ligands are dissociated by light absorption and/or secondary electrons produced thereby, and are crosslinked with adjacent chains through oxo bonds and thus enable the negative tone patterning which may not be removed by an organic developing solution. This organotin polymer exhibits greatly improved sensitivity as well as maintains a resolution and line edge roughness, but the patterning characteristics need to be additionally improved for commercial availability.

### SUMMARY

Some embodiments of the present disclosure provide a semiconductor photoresist composition having excellent sensitivity characteristics.

Some embodiments provide a method of forming a pattern using the semiconductor photoresist composition.

A semiconductor photoresist composition according to some embodiments includes an organometallic compound; a vinyl group-containing acid compound; and a solvent.

The vinyl group-containing acid compound may include one or more selected from at least one carboxyl group, at least one sulfonic acid group, and at least one phosphonic acid group.

The vinyl group-containing acid compound may be represented by any one selected from Chemical Formula 1 to Chemical Formula 3.

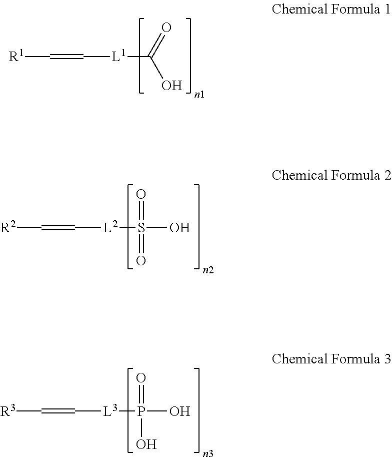

In Chemical Formula 1 to Chemical Formula 3,
R¹ to R³ are each independently hydrogen or a substituted or unsubstituted C1 to C10 alkyl group,
L¹ to L³ are each independently a single bond (e.g., a single covalent bond), a substituted or unsubstituted C1 to C10 alkylene group, or a substituted or unsubstituted C6 to C20 arylene group, and
n1 to n3 are each independently an integer of 1 or more.

R¹ to R³ may each independently be hydrogen or a substituted or unsubstituted C1 to C5 alkyl group, and

L¹ to L³ may each independently be a single bond (e.g., a single covalent bond), a substituted or unsubstituted C1 to C5 alkylene group, a substituted or unsubstituted phenylene group, a substituted or unsubstituted biphenylene group, or a substituted or unsubstituted naphthylene group.

The vinyl group-containing acid compound may be one or more selected from 4-vinyl benzoic acid, vinyl sulfonic acid, vinyl phosphonic acid, vinyl acetic acid, (meth)acrylic acid, and 1-vinylpyrazole-4-carboxylic acid.

The vinyl group-containing acid compound may be included in an amount of about 0.1 to about 15 wt % based on 100 wt % of the semiconductor photoresist composition.

The organometallic compound may be included in an amount of about 1 wt % to about 30 wt % based on 100 wt % of the semiconductor photoresist composition.

The organometallic compound may include tin (Sn).

The organometallic compound may include at least one selected from an organic oxy group and an organic carbonyloxy group.

The organometallic compound may be represented by Chemical Formula 4.

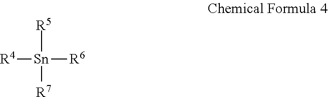

In Chemical Formula 4,
R⁴ is selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, and L^{a}-O—R^{a} (wherein L^{a} is a substituted or unsubstituted C1 to C20 alkylene group and R^{a} is a substituted or unsubstituted C1 to C20 alkyl group),
R⁵ to R⁷ are each independently selected from —OR^{b} or —OC(═O)R^{c},
R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

R⁴ may be a substituted or unsubstituted C1 to C8 alkyl group, a substituted or unsubstituted C3 to C8 cycloalkyl group, a substituted or unsubstituted C2 to C8 aliphatic unsaturated organic group including one or more double bonds or triple bonds, a substituted or unsubstituted C6 to C20 aryl group, a substituted or unsubstituted C4 to C20 heteroaryl group, a carbonyl group, ethoxy group, propoxy group, or a combination thereof,
R^{a} may be a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof, and
R^{b} may be hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof.

R⁴ may be a methyl group, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, a formyl group, an acetyl group, a propanoyl group, a butanoyl group, a pentanoyl group, an ethoxy group, a propoxy group, or a combination thereof,
R^{a} may be an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a combination thereof, and
R^{b} may be hydrogen, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a combination thereof.

The organometallic compound and the vinyl group-containing acid compound may be included in a weight ratio of about 99:1 to about 80:20.

The semiconductor photoresist composition may further include additives such as, for example, a surfactant, a leveling agent, a crosslinking agent, or a combination thereof.

The method of forming patterns according to some embodiments includes forming an etching-objective layer on a substrate, coating the semiconductor photoresist composition on the etching-objective layer to form a photoresist layer, patterning the photoresist layer to form a photoresist pattern, and etching the etching-objective layer using the photoresist pattern as an etching mask.

The photoresist pattern may be formed using light having a wavelength of about 5 nm to about 150 nm.

The method of forming patterns may further include providing a resist underlayer between the substrate and the photoresist layer.

The photoresist pattern may have a width of about 5 nm to about 100 nm.

A semiconductor photoresist composition according to some embodiments realize excellent sensitivity.

### BRIEF DESCRIPTION OF DRAWINGS

The accompanying drawings, together with the specification, illustrate embodiments of the subject matter of the present disclosure, and, together with the description, serve to explain principles of embodiments of the subject matter of the present disclosure.

FIGS. 1-5 are cross-sectional views for explaining a method of forming patterns using a semiconductor photoresist composition according to some embodiments.

### DETAILED DESCRIPTION

Hereinafter, referring to the drawings, embodiments of the present disclosure are described in more detail. In the following description of embodiments of the present disclosure, well-known functions or constructions will not be described in order to clarify the description of the subject matter of the present disclosure.

In order to clearly illustrate embodiments of the present disclosure, certain description and/or relationships may be omitted, and throughout the disclosure, the same or similar configuration elements may be designated by the same reference numerals. Also, because the size and thickness of each configuration shown in the drawing may be arbitrarily shown for better understanding and ease of description, the present disclosure is not necessarily limited thereto.

In the drawings, the thickness of layers, films, panels, regions, etc., may be enlarged for clarity. In the drawings, the thickness of a part of layers or regions, etc., may be exaggerated for clarity. It will be understood that when an element such as a layer, film, region, or substrate is referred to as being “on” another element, it can be directly on the other element or intervening elements may also be present.

As used herein, “substituted” refers to replacement of a hydrogen atom by deuterium, a halogen, a hydroxy group, a thiol group, a cyano group, a nitro group, —NRR′ (wherein, R and R′ are each independently hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), —SiRR′R″ (wherein, R, R′, and R″ are each independently hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, a C1 to C20 sulfide group, or a combination thereof. “Unsubstituted” refers to non-replacement of a hydrogen atom by another substituent and remaining of the hydrogen atom.

As used herein, when a definition is not otherwise provided, “an alkyl group” refers to a linear or branched aliphatic hydrocarbon group. The alkyl group may be “a saturated alkyl group” without any double bond or triple bond.

The alkyl group may be a C1 to C8 alkyl group. For example, the alkyl group may be a C1 to C7 alkyl group, a C1 to C6 alkyl group, or a C1 to C5 alkyl group. For example, the C1 to C5 alkyl group may be a methyl group, an ethyl group, a propyl group, an isopropyl group, an n-butyl group, an isobutyl group, a sec-butyl group, a tert-butyl group, or a 2,2-dimethylpropyl group.

As used herein, when a definition is not otherwise provided, “cycloalkyl group” refers to a monovalent cyclic aliphatic hydrocarbon group.

The cycloalkyl group may be a C3 to C8 cycloalkyl group, for example, a C3 to C7 cycloalkyl group, a C3 to C6 cycloalkyl group, a C3 to C5 cycloalkyl group, or a C3 to C4 cycloalkyl group. For example, the cycloalkyl group may be a cyclopropyl group, a cyclobutyl group, a cyclopentyl group, or a cyclohexyl group, but is not limited thereto.

As used herein, “aliphatic unsaturated organic group” refers to a hydrocarbon group including a bond in which the bond between the carbon and carbon atom in the molecule is a double bond, a triple bond, or a combination thereof.

The aliphatic unsaturated organic group may be a C2 to C8 aliphatic unsaturated organic group. For example, the aliphatic unsaturated organic group may be a C2 to C7 aliphatic unsaturated organic group, a C2 to C6 aliphatic unsaturated organic group, a C2 to C5 aliphatic unsaturated organic group, or a C2 to C4 aliphatic unsaturated organic group. For example, the C2 to C4 aliphatic unsaturated organic group may be a vinyl group, an ethynyl group, an allyl group, a 1-propenyl group, a 1-methyl-1-propenyl group, a 2-propenyl group, a 2-methyl-2-propenyl group, a 1-propynyl group, a 1-methyl-1 propynyl group, a 2-propynyl group, a 2-methyl-2-propynyl group, a 1-butenyl group, a 2-butenyl group, a 3-butenyl group, a 1-butynyl group, a 2-butynyl group, or a 3-butynyl group.

As used herein, “aryl group” refers to a substituent in which all atoms in the cyclic substituent have a p-orbital and these p-orbitals are conjugated and may include a monocyclic or fused ring polycyclic functional group (e.g., rings sharing adjacent pairs of carbon atoms) functional group.

As used herein, “heteroaryl group” may refer to an aryl group including at least one heteroatom selected from N, O, S, P, and Si. Two or more heteroaryl groups are linked by a sigma bond directly, or when the heteroaryl group includes two or more rings, the two or more rings may be fused together. When the heteroaryl group is a fused ring, each ring may include one to three heteroatoms.

As used herein, unless otherwise defined, “alkenyl group” refers to an aliphatic unsaturated alkenyl group including at least one double bond as a linear or branched aliphatic hydrocarbon group.

As used herein, unless otherwise defined, “alkynyl group” refers to an aliphatic unsaturated alkynyl group including at least one triple bond as a linear or branched aliphatic hydrocarbon group.

Hereinafter, a semiconductor photoresist composition according to some embodiments is described.

The semiconductor photoresist composition according to some embodiments may include an organometallic compound, a vinyl group-containing acid compound, and a solvent.

By including a vinyl group-containing acid compound, the semiconductor photoresist composition can improve sensitivity characteristics as the polymerization reaction progresses by radicals generated from EUV.

The vinyl group-containing acid compound may include one or more selected from at least one carboxyl group, at least one sulfonic acid group, and at least one phosphonic acid group.

The vinyl group-containing acid compound may be represented by any one selected from Chemical Formula 1 to Chemical Formula 3.

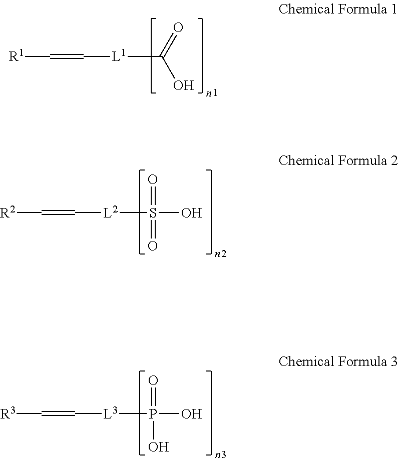

### In Chemical Formula 1 to Chemical Formula 3,

R¹ to R³ are each independently hydrogen or a substituted or unsubstituted C1 to C10 alkyl group,
L¹ to L³ are each independently a single bond (e.g., a single covalent bond), a substituted or unsubstituted C1 to C10 alkylene group, or a substituted or unsubstituted C6 to C20 arylene group, and
n1 to n3 are each independently an integer of 1 or more.

In some embodiments, when each of L¹ to L³ is a single bond (e.g., a single covalent bond), the carboxyl group, sulfonic acid group, and phosphonic acid group may each be monosubstituted, and in some embodiments, n1 to n3 may each be 1.

In some embodiments, when L¹ to L³ are each independently a substituted or unsubstituted C1 to C10 alkylene group, the carboxyl group, sulfonic acid group and phosphonic acid group may each mono- or bi-substituted, and in some embodiments, n1 to n3 may each independently be an integer of 1 or 2.

In some embodiments, when L¹ to L³ are each independently substituted or unsubstituted C6 to C20 arylene group, the carboxyl group, sulfonic acid group, and phosphonic acid group may each be substituted at substitutable positions in the C6 to C20 arylene group and for example, n1 to n3 may each independently be one of the integers from 1 to 10. For example, n1 to n3 may each independently be one selected from integers from 1 to 8. In some embodiments, n1 to n3 may each independently be one selected from integers from 1 to 5. For example, n1 to n3 may each independently be one selected from integers from 1 to 3.

R¹ to R³ may each independently be hydrogen or a substituted or unsubstituted C1 to C5 alkyl group,
L¹ to L³ may each independently be a single bond (e.g., a single covalent bond), a substituted or unsubstituted C1 to C5 alkylene group, a substituted or unsubstituted phenylene group, a substituted or unsubstituted biphenylene group, or a substituted or unsubstituted naphthylene group.

The vinyl group-containing acid compound may be one or more selected from 4-vinyl benzoic acid, vinyl sulfonic acid, vinyl phosphonic acid, vinyl acetic acid, (meth)acrylic acid, and 1-vinylpyrazole-4-carboxylic acid.

The vinyl group-containing acid compound may be included in an amount of about 0.1 to about 15 wt % based on 100 wt % of the semiconductor photoresist composition.

The organometallic compound may be included in an amount of about 1 wt % to about 30 wt % based on 100 wt % of the semiconductor photoresist composition.

The organometallic compound may include tin (Sn).

The organometallic compound may include at least one selected from an organic oxy group and an organic carbonyloxy group.

The organometallic compound may be represented by Chemical Formula 4.

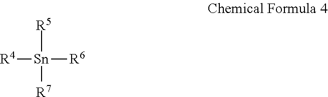

In Chemical Formula 4,
R⁴ is selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, and L^{a}-O—R^{a} (wherein L^{a} is a substituted or unsubstituted C1 to C20 alkylene group and R^{a} is a substituted or unsubstituted C1 to C20 alkyl group),
R⁵ to R⁷ are each independently —OR^{b} or —OC(═O)R^{c},
R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

In some embodiments, the compound represented by Chemical Formula 4 includes —OR^{b} or —OC(═O)R^{c} as a ligand, so that a pattern formed using a semiconductor photoresist composition containing it can exhibit excellent limiting resolution.

In some embodiments, the —OR^{b} or —OC(═O)R^{c} ligand can determine the solubility of the compound represented by Chemical Formula 4 in a solvent.

R⁴ may be a substituted or unsubstituted C1 to C8 alkyl group, a substituted or unsubstituted C3 to C8 cycloalkyl group, a substituted or unsubstituted C2 to C8 aliphatic unsaturated organic group including one or more double bonds or triple bonds, a substituted or unsubstituted C6 to C20 aryl group, a substituted or unsubstituted C4 to C20 heteroaryl group, a carbonyl group, ethoxy group, propoxy group, or a combination thereof,
R^{a} may be a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof, and
R^{b} may be hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof.

R⁴ may be a methyl group, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, a formyl group, an acetyl group, a propanoyl group, a butanoyl group, a pentanoyl group, an ethoxy group, a propoxy group, or a combination thereof,
R^{a} may be an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a combination thereof, and
R^{b} may be hydrogen, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a combination thereof.

The semiconductor photoresist composition according to some embodiments may include the organometallic compound and the vinyl group-containing acid compound in a weight ratio of about 99:1 to about 80:20. For example, the semiconductor photoresist composition may include the organometallic compound and the vinyl group-containing acid compound in a weight ratio of about 95:5 to about 85:15.

When the weight ratio of the organometallic compound and the vinyl group-containing acid compound satisfies the above ranges, a semiconductor photoresist composition having excellent sensitivity can be provided.

The semiconductor photoresist composition according to some embodiments may improve the sensitivity of the photoresist by including the organometallic compound and the vinyl group-containing acid compound within the above content ranges.

The solvent of the semiconductor photoresist composition according to some embodiments may be an organic solvent, and may include for example an aromatic compound (e.g., xylene, toluene, etc.), an alcohol (e.g., 4-methyl-2-pentenol, 4-methyl-2-propanol, 1-butanol, methanol, isopropyl alcohol, 1-propanol), ethers (e.g., anisole, tetrahydrofuran), an ester (n-butyl acetate, propylene glycol monomethyl ether acetate, ethyl acetate, ethyl lactate), a ketone (e.g., methyl ethyl ketone, 2-heptanone), or a mixture thereof, but is not limited thereto.

The semiconductor photoresist composition according to some embodiments may further include a resin in addition to the above-mentioned organometallic compound, vinyl group-containing acid compound, and solvent.

The resin may be a phenolic resin including at least one aromatic moiety of Group 2.

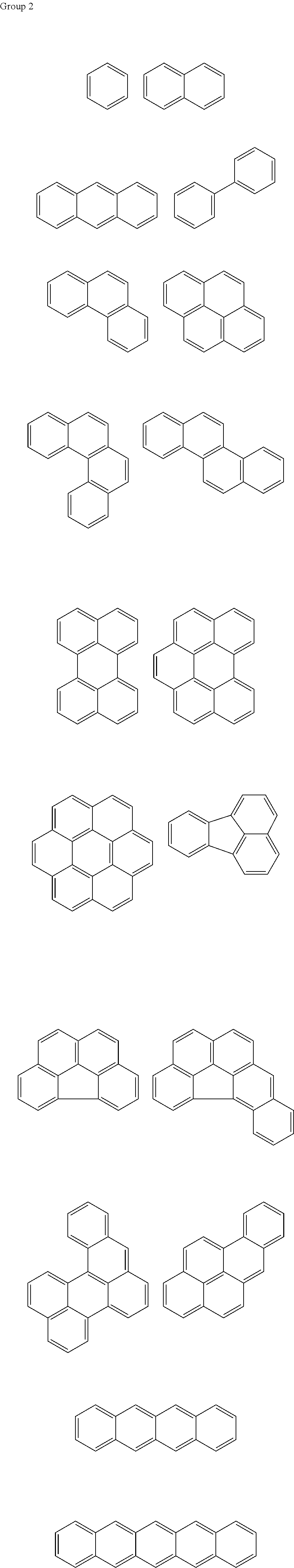

The resin may have a weight average molecular weight of about 500 to about 20,000.

The resin may be included in an amount of about 0.1 wt % to about 50 wt % based on the total amount of the semiconductor photoresist composition.

When the resin is included in the above content range, it may have excellent etch resistance and heat resistance.

In some embodiments, the semiconductor photoresist composition may consist of the organometallic compound, the solvent, and the resin. However, the semiconductor photoresist composition according to some embodiments may further include additives as needed. Examples of the additives may be a surfactant, a crosslinking agent, a leveling agent, an organic acid, a quencher, or a combination thereof.

The surfactant may include for example an alkyl benzene sulfonate salt, an alkyl pyridinium salt, polyethylene glycol, a quaternary ammonium salt, or a combination thereof, but is not limited thereto.

The crosslinking agent may be for example a melamine-based crosslinking agent, a substituted urea-based crosslinking agent, an acryl-based crosslinking agent, an epoxy-based crosslinking agent, and/or a polymer-based crosslinking agent, but is not limited thereto. It may be a crosslinking agent having at least two crosslinking forming substituents, for example, a compound such as methoxymethylated glycoluril, butoxymethylated glycoluril, methoxymethylated melamine, butoxymethylated melamine, methoxymethylated benzoguanamine, butoxymethylated benzoguanamine, 4-hydroxybutyl acrylate, acrylic acid, urethane acrylate, acryl methacrylate, 1,4-butanediol diglycidyl ether, glycidol, diglycidyl 1,2-cyclohexane dicarboxylate, trimethylpropane triglycidyl ether, 1,3-bis(glycidoxypropyl)tetramethyldisiloxane, methoxymethylated urea, butoxymethylated urea, and/or methoxymethylated thiourea, and/or the like.

The leveling agent may be used for improving coating flatness during printing and may be any suitable commercially available leveling agent.

The organic acid may include p-toluenesulfonic acid, benzenesulfonic acid, p-dodecylbenzenesulfonic acid, 1,4-naphthalenedisulfonic acid, methanesulfonic acid, a fluorinated sulfonium salt, malonic acid, citric acid, propionic acid, methacrylic acid, oxalic acid, lactic acid, glycolic acid, succinic acid, or a combination thereof, but is not limited thereto.

The quencher may be diphenyl (p-tolyl) amine, methyl diphenyl amine, triphenyl amine, phenylenediamine, naphthylamine, diaminonaphthalene, or a combination thereof.

A use amount of the additives may be controlled depending on suitable or desired properties.

In some embodiments, the semiconductor photoresist composition may further include a silane coupling agent as an adherence enhancer in order to improve a close-contacting force with the substrate (e.g., in order to improve adherence of the semiconductor photoresist composition to the substrate). The silane coupling agent may be for example a silane compound including a carbon-carbon unsaturated bond such as, for example, vinyltrimethoxysilane, vinyl triethoxysilane, vinyl trichlorosilane, vinyl tris(β-methoxyethoxy)silane; and/or 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyl diethoxysilane; trimethoxy[3-(phenylamino)propyl]silane, and/or the like, but is not limited thereto.

The semiconductor photoresist composition may be formed into a pattern having a high aspect ratio without a collapse. Accordingly, in order to form a fine pattern having a width of, for example, about 5 nm to about 100 nm, for example, about 5 nm to about 80 nm, for example, about 5 nm to about 70 nm, for example, about 5 nm to about 50 nm, for example, about 5 nm to about 40 nm, for example, about 5 nm to about 30 nm, or for example, about 5 nm to about 20 nm, the semiconductor photoresist composition may be used for a photoresist process using light having a wavelength in a range from about 5 nm to about 150 nm, for example, about 5 nm to about 100 nm, about 5 nm to about 80 nm, about 5 nm to about 50 nm, about 5 nm to about 30 nm, or about 5 nm to about 20 nm. Accordingly, the semiconductor photoresist composition according to some embodiments may be used to realize extreme ultraviolet lithography using an EUV light source having a wavelength of about 13.5 nm.

According to some embodiments, a method of forming patterns using the aforementioned semiconductor photoresist composition is provided. For example, the manufactured pattern may be a photoresist pattern.

The method of forming patterns according to some embodiments includes forming an etching-objective layer on a substrate, coating the semiconductor photoresist composition on the etching-objective layer to form a photoresist layer, patterning the photoresist layer to form a photoresist pattern, and etching the etching-objective layer using the photoresist pattern as an etching mask.

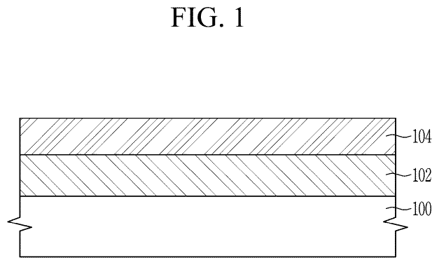

Hereinafter, an embodiment of a method of forming patterns using the semiconductor photoresist composition is described referring to FIGS. 1-5. FIGS. 1-5 are cross-sectional views illustrating a method of forming patterns using a semiconductor photoresist composition according to some embodiments.

Referring to FIG. 1, an object for etching is prepared. The object for etching may be a thin film 102 on a semiconductor substrate 100. Hereinafter, the object for etching is limited to the thin film 102. A whole surface of the thin film 102 is washed to remove impurities and the like remaining thereon. The thin film 102 may be for example a silicon nitride layer, a polysilicon layer, and/or a silicon oxide layer.

Subsequently, the resist underlayer composition for forming a resist underlayer 104 is spin-coated on the surface of the washed thin film 102. However, the embodiment is not limited thereto, and various suitable coating methods such as, for example, a spray coating, a dip coating, a knife edge coating, a printing method, for example, an inkjet printing and/or a screen printing, and/or the like may be used.

The coating process of the resist underlayer may be omitted, and hereinafter, a process including a coating of the resist underlayer is described.

Then, the coated composition is dried and baked to form the resist underlayer 104 on the thin film 102. The baking may be performed at about 100° C. to about 500° C., or, for example, about 100° C. to about 300° C.

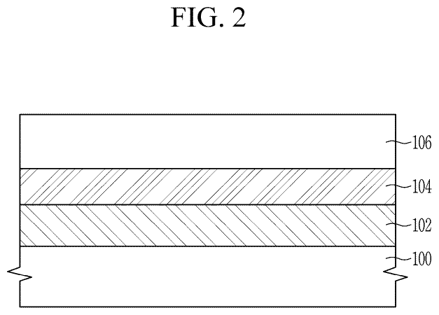

The resist underlayer 104 is formed between the substrate 100 and a photoresist layer 106 (see FIG. 2) and thus may prevent non-uniformity and decreased pattern-forming capability of a photoresist line width when a ray reflected from on the interface between the substrate 100 and the photoresist layer 106 and/or a hardmask between layers is scattered into an unintended photoresist region.

Referring to FIG. 2, the photoresist layer 106 is formed by coating the semiconductor photoresist composition on the resist underlayer 104. The photoresist layer 106 is obtained by coating the aforementioned semiconductor photoresist composition on the thin film 102 on the substrate 100 and then, curing it through a heat treatment.

In some embodiments, the formation of a pattern by using the semiconductor photoresist composition may include coating the semiconductor photoresist composition on the substrate 100 having the thin film 102 through spin coating, slit coating, inkjet printing, and/or the like and then, drying it to form the photoresist layer 106.

The semiconductor photoresist composition has already been illustrated in detail and redundant description thereof may not be repeated again.

Subsequently, a substrate 100 having the photoresist layer 106 is subjected to a first baking process. The first baking process may be performed at about 80° C. to about 120° C.

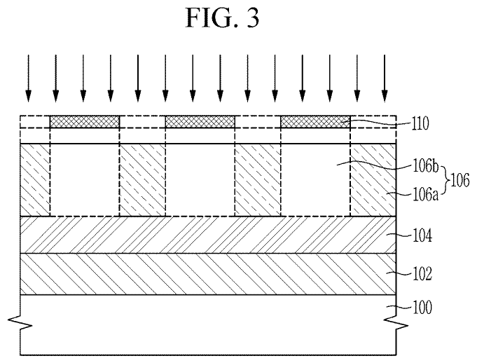

Referring to FIG. 3, the photoresist layer 106 may be selectively exposed using a patterned mask 110.

For example, the exposure may use an activation radiation including light having a high energy wavelength such as EUV (extreme ultraviolet; a wavelength of about 13.5 nm), an E-Beam (an electron beam), and/or the like as well as a short wavelength such as an i-line (a wavelength of about 365 nm), a KrF excimer laser (a wavelength of about 248 nm), an ArF excimer laser (a wavelength of about 193 nm), and/or the like.

In some embodiments, light for the exposure according to some embodiments may have a short wavelength in a range from about 5 nm to about 150 nm and a high energy wavelength, for example, EUV (extreme ultraviolet; a wavelength of 13.5 nm), an E-Beam (an electron beam), and/or the like.

An exposed region 106a of the photoresist layer 106 has a different solubility from a non-exposed region 106b of the photoresist layer 106 by forming a polymer by a crosslinking reaction such as a condensation reaction between organometallic compounds.

Subsequently, the substrate 100 is subjected to a second baking process. The second baking process may be performed at a temperature of about 90° C. to about 200° C. The exposed region 106a of the photoresist layer 106 becomes easily indissoluble regarding a developing solution due to the second baking process.

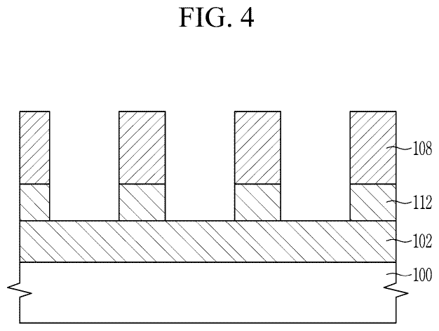

In FIG. 4, the non-exposed region 106b of the photoresist layer is dissolved and removed using the developing solution to form a photoresist pattern 108. In some embodiments, the non-exposed region 106b of the photoresist layer is dissolved and removed by using an organic solvent such as, for example, 2-heptanone and/or the like to complete the photoresist pattern 108 corresponding to the negative tone image.

As described above, a developing solution used in a method of forming patterns according to some embodiments may be an organic solvent. The organic solvent used in the method of forming patterns according to some embodiments may be for example ketones such as methylethylketone, acetone, cyclohexanone, 2-heptanone, and/or the like, alcohols such as 4-methyl-2-propanol, 1-butanol, isopropanol, 1-propanol, methanol, and/or the like, esters such as propylene glycol monomethyl ether acetate, ethyl acetate, ethyl lactate, n-butyl acetate, butyrolactone, and/or the like, aromatic compounds such as benzene, xylene, toluene, and/or the like, or a combination thereof.

However, the photoresist pattern according to some embodiments is not necessarily limited to the negative tone image but may be formed to have a positive tone image. Herein, a developer used for forming the positive tone image may be a quaternary ammonium hydroxide composition such as tetraethylammonium hydroxide, tetrapropylammonium hydroxide, tetrabutylammonium hydroxide, or a combination thereof.

As described above, exposure to light having a high energy such as EUV (extreme ultraViolet; a wavelength of 13.5 nm), an E-Beam (an electron beam), and/or the like as well as light having a wavelength such as i-line (wavelength of about 365 nm), KrF excimer laser (wavelength of about 248 nm), ArF excimer laser (wavelength of about 193 nm), and/or the like may provide a photoresist pattern 108 having a width of about 5 nm to about 100 nm. For example, the photoresist pattern 108 may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm.

In some embodiments, the photoresist pattern 108 may have a pitch of having a half-pitch of less than or equal to about 50 nm, for example less than or equal to about 40 nm, for example less than or equal to about 30 nm, for example less than or equal to about 20 nm, or for example less than or equal to about 15 nm, and a line width roughness of less than or equal to about 10 nm, less than or equal to about 5 nm, less than or equal to about 3 nm, or less than or equal to about 2 nm.

Subsequently, the photoresist pattern 108 is used as an etching mask to etch the resist underlayer 104. Through this etching process, an organic layer pattern 112 is formed. The organic layer pattern 112 also may have a width corresponding to that of the photoresist pattern 108.

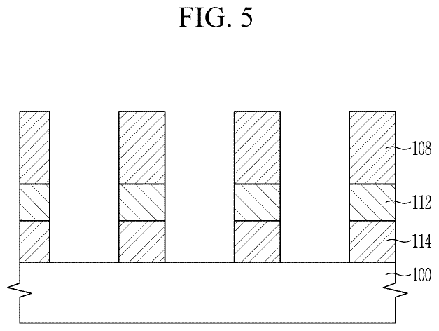

Referring to FIG. 5, the exposed thin film 102 is etched by applying the photoresist pattern 108 as an etching mask. As a result, the thin film is formed as a thin film pattern 114.

The etching of the thin film 102 may be for example dry etching using an etching gas and the etching gas may be for example CHF₃, CF₄, Cl₂, BCl₃, or a mixed gas thereof.

In the exposure process, the thin film pattern 114 formed by using the photoresist pattern 108 formed through the exposure process performed by using an EUV light source may have a width corresponding to that of the photoresist pattern 108. For example, the thin film pattern 114 may have a width of 5 nm to 100 nm which is equal to that of the photoresist pattern 108. For example, the thin film pattern 114 formed by using the photoresist pattern 108 formed through the exposure process performed by using an EUV light source may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm, and, for example, a width of less than or equal to about 20 nm, like that of the photoresist pattern 108.

Hereinafter, embodiments of the present disclosure will be described in more detail through examples of the preparation of the aforementioned semiconductor photoresist composition. However, the present disclosure is technically not restricted by the following examples.

### Synthesis of Organometallic Compounds

### Synthesis Example 1

In a 250 ml 2-necked round-bottomed flask, 20 g (51.9 mmol) of Ph₃SnCl is dissolved in 70 ml of THE (tetrahydrofuran) and then, cooled to 0° C. in an ice bath. Subsequently, a 1 M butyl magnesiumchloride (BuMgCI) THE solution (62.3 mmol) is slowly added dropwise thereto. When the dropwise addition is completed, the resultant mixture is stirred at 25° C. for 12 hours to obtain a compound represented by Chemical Formula 5a.

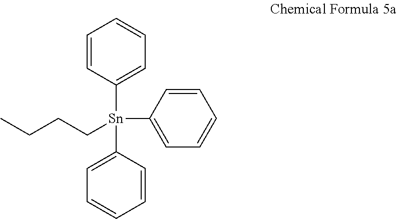 [SMILES: CCC[CH2][Sn]([c]1ccccc1)([c]1ccccc1)[c]1ccccc1]

The compound represented by Chemical Formula 5a (10 g, 24.6 mmol) is dissolved in 50 mL of CH₂Cl₂ and then, 3 equivalents (73.7 mmol) of a 2 M HCl diethyl ether solution is slowly added dropwise thereto at −78° C. for 30 minutes. After stirring the obtained mixture at 25° C. for 12 hours, the solvent is concentrated and vacuum-distilled therefrom to obtain a compound represented by Chemical Formula 5b.

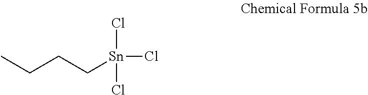

Subsequently, 10 g (25.6 mmol) of the compound represented by Chemical Formula 5b is slowly added in a dropwise fashion to 25 mL of acetic acid at 25° C. and then, heated under reflux for 12 hours. After decreasing the temperature to 25° C., the acetic acid is vacuum-distilled to finally obtain a compound represented by Chemical Formula 5.

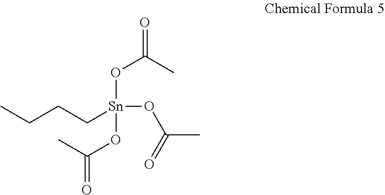 [SMILES: CCC[CH2][Sn]([O]C(C)=O)([O]C(C)=O)[O]C(C)=O]

### Synthesis Example 2

The compound of Chemical Formula 5a (10 g, 24.6 mmol) is dissolved in 50 mL of CH₂Cl₂, and 3 equivalents (73.7 mmol) of a 2 M HCl diethyl ether solution is slowly added in a dropwise fashion thereto at −78° C. for 30 minutes. After stirring the obtained mixture at 25° C. for 12 hours, the solvent is concentrated and vacuum-distilled therefrom to obtain a compound represented by Chemical Formula 6b.

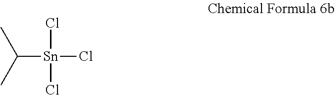

Subsequently, 10 g (25.6 mmol) of the compound represented by Chemical Formula 6b is mixed together with 25 mL of a mixed solution of propionic acid and methacrylic acid (a volume ratio=3:1) and then, heated under reflux for 12 hours. After increasing the temperature to 25° C., a compound represented by Chemical Formula 6 is finally obtained through vacuum-distillation.

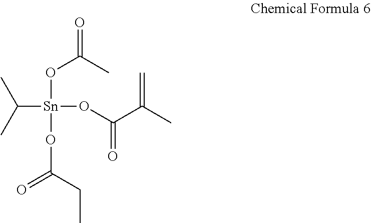 [SMILES: C=C(C)C(=O)[O][Sn]([O]C(C)=O)([O]C(=O)CC)[CH](C)C]

### Synthesis Example 3

3.7 g of Mg is vacuum-dried in a 500 mL round-bottomed flask, and 12 is added thereto, and also, 120 ml of THE is added thereto. Subsequently, 8.76 g of 1,4-bis(bromomethyl)benzene and 20 g of tributyltin chloride are diluted in 120 ml of THE and then, slowly added to the round-bottomed flask and then, stirred. Then, the resultant is washed with a NH₄Cl solution and a NaCl solution and then, dried and then, dissolved in toluene, and 4.3 g (16.7 mmol) of SnCl₄ is slowly added thereto at a low temperature and then, stirred for 2 hours. After removing the solvents therefrom and then, performing extraction by using acetonitrile and pentene, collecting an acetonitrile layer therefrom, blowing off the solvents therefrom, and adding it again to DCM, 1.625 g of triethylamine is slowly added thereto, while stirring, and acetic acid is added thereto at a low temperature and then, stirred for 1 hour. Subsequently, after removing a resultant solid with a filter, the residue is concentrated to obtain a compound represented by Chemical Formula 7.

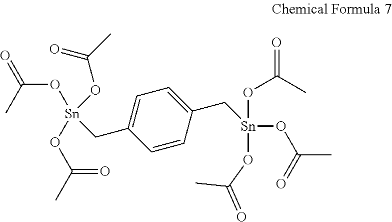 [SMILES: CC(=O)[O][Sn]([CH2]c1ccc([CH2][Sn]([O]C(C)=O)([O]C(C)=O)[O]C(C)=O)cc1)([O]C(C)=O)[O]C(C)=O]

### Preparation of Semiconductor Photoresist Compositions

### Examples 1 to 7 and Comparative Examples 1 to 5

Each of the compounds represented by Chemical Formulas 5 to 7 prepared by Synthesis Examples 1 to 3 and an acid compound in a weight ratio shown in Table 1 are dissolved in propylene glycol methyl ether acetate at a concentration of 3 wt % and then, filtered with a 0.1 μm PTFE (polytetrafluoroethylene) syringe filter to prepare respective semiconductor photoresist compositions according to Examples 1 to 7 and Comparative Examples 1 to 5.

A circular silicon wafer having a diameter of 4 inches and a native-oxide surface is used as a substrate for thin film coating, which is treated in a UV ozone cleaning system for 10 minutes before coating the thin film. On the treated substrate, each of the semiconductor photoresist compositions of Examples 1 to 7 and Comparative Examples 1 to 5 is respectively spin-coated at 1500 rpm for 30 seconds and then, post-apply baked (PAB) at 110° C. for 60 seconds to form a photoresist thin film.

The film after the coating and the baking is measured with respect to a thickness by using ellipsometry, wherein the thickness is about 25 nm.

### Evaluation 1: Sensitivity Evaluation

A linear array of 50 circular pads each having a diameter of 500 μm is projected onto the wafers respectively coated with each of the photoresist compositions of Examples 1 to 7 and Comparative Examples 1 and 5 by using EUV light (Micro Exposure Tool (MET), Lawrence Berkeley National Laboratory). An EUV dose is increasingly applied to each pad by adjusting pad exposure time.

Subsequently, the resist and the substrate are exposed on a hotplate at 160° C. for 120 seconds and then, post-exposure baked (PEB). The baked film is dipped in a developing solution (2-heptanone) for 30 seconds and additionally washed with the same developing solution for 10 seconds to form a negative tone image, that is, to remove a nonexposed coating region. Finally, the exposed pads are baked on a hotplate at 150° C. for 2 minutes is performed, thereby terminating the process.

The exposed pads are measured with respect to a residual resist thickness by using an ellipsometer. The residual thickness is measured for each exposure dose and graphed as a function with the exposure dose to evaluate Dg (an energy level at which the development is completed) for each type of resist according to the following criteria, and the results are shown in Table 1.

### Evaluation Criteria (Dg Value)

A: Less than 16 mJ/cm²
B: greater than or equal to 16 mJ/cm²

TABLE 1

| | Organometallic | Acid compound | Sensitivity |
|---|---|---|---|
| | compound (wt %) | (wt %) | (Eop/mJ) |
| Example 1 | Chemical Formula 5 | vinyl acetic acid | 95 |
| | (2.85) | (0.15) | |
| Example 2 | Chemical Formula 5 | 4-vinylbenzoic acid | 98 |
| | (2.85) | (0.15) | |
| Example 3 | Chemical Formula 5 | vinyl sulfonic acid | 97 |
| | (2.85) | (0.15) | |
| Example 4 | Chemical Formula 5 | vinyl phosphonic acid | 93 |
| | (2.85) | (0.15) | |
| Example 5 | Chemical Formula 5 | vinyl phosphonic acid | 87 |
| | (2.55) | (0.45) | |
| Example 6 | Chemical Formula 6 | vinyl phosphonic acid | 85 |
| | (2.85) | (0.15) | |
| Example 7 | Chemical Formula 7 | vinyl phosphonic acid | 90 |
| | (2.85) | (0.15) | |
| Comparative | Chemical Formula 5 | — | 110 |
| Example 1 | (3) | | |
| Comparative | Chemical Formula 5 | acetic acid | 105 |
| Example 2 | (2.85) | (0.15) | |
| Comparative | Chemical Formula 5 | benzoic acid | 104 |
| Example 3 | (2.85) | (0.15) | |
| Comparative | Chemical Formula 5 | sulfonic acid | 107 |
| Example 4 | (2.85) | (0.15) | |
| Comparative | Chemical Formula 5 | methyl phosphonic acid | 100 |
| Example 5 | (2.85) | (0.15) | |

Referring to the results of Table 1, patterns formed by using the semiconductor photoresist compositions according to Examples 1 to 7 exhibit excellent sensitivity, compared with patterns formed by using semiconductor photoresist compositions according to Comparative Examples 1 to 5.

Hereinbefore, example embodiments of the present disclosure have been described and illustrated, however, it should be apparent to a person having ordinary skill in the art that the present disclosure is not limited to the embodiments as described, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the appended claims of the present disclosure, and equivalents thereof.

Description of Symbols

| | |
|---|---|
| 100: substrate | 102: thin film |
| 104: resist underlayer | 106: photoresist layer |
| 106a: exposed region | 106b: non-exposed region |
| 108: photoresist pattern | 112: organic layer pattern |
| 110: patterned mask | 114: thin film pattern |

What is claimed is:

1. A semiconductor photoresist composition, comprising:
an organometallic compound;
a vinyl group-containing acid compound; and
a solvent.

2. The semiconductor photoresist composition as claimed in claim 1, wherein:
the vinyl group-containing acid compound comprises one or more selected from at least one carboxyl group, at least one sulfonic acid group, and at least one phosphonic acid group.

3. The semiconductor photoresist composition as claimed in claim 1, wherein:
the vinyl group-containing acid compound is represented by any one selected from Chemical Formula 1 to Chemical Formula 3: 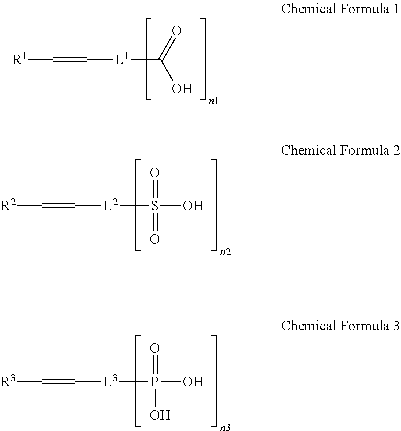
wherein, in Chemical Formula 1 to Chemical Formula 3,
R¹ to R³ are each independently hydrogen or a substituted or unsubstituted C1 to C10 alkyl group,
L¹ to L³ are each independently a single bond, a substituted or unsubstituted C1 to C10 alkylene group, or a substituted or unsubstituted C6 to C20 arylene group, and
n1 to n3 are each independently an integer of 1 or more.

4. The semiconductor photoresist composition as claimed in claim 3, wherein:
R¹ to R³ are each independently hydrogen or a substituted or unsubstituted C1 to C5 alkyl group, and
L¹ to L³ are each independently a single bond, a substituted or unsubstituted C1 to C5 alkylene group, a substituted or unsubstituted phenylene group, a substituted or unsubstituted biphenylene group, or a substituted or unsubstituted naphthylene group.

5. The semiconductor photoresist composition as claimed in claim 1, wherein:
the vinyl group-containing acid compound comprises one or more selected from 4-vinyl benzoic acid, vinyl sulfonic acid, vinyl phosphonic acid, vinyl acetic acid, (meth)acrylic acid, and 1-vinylpyrazole-4-carboxylic acid.

6. The semiconductor photoresist composition as claimed in claim 1, wherein:
the vinyl group-containing acid compound is included in an amount of about 0.1 to about 15 wt % based on 100 wt % of the semiconductor photoresist composition.

7. The semiconductor photoresist composition as claimed in claim 1, wherein:
the organometallic compound is included in an amount of about 1 wt % to about 30 wt % based on 100 wt % of the semiconductor photoresist composition.

8. The semiconductor photoresist composition as claimed in claim 1, wherein:
the organometallic compound comprises tin (Sn).

9. The semiconductor photoresist composition as claimed in claim 1, wherein:
the organometallic compound comprises at least one selected from an organic oxy group and an organic carbonyloxy group.

10. The semiconductor photoresist composition as claimed in claim 1, wherein:
the organometallic compound is represented by Chemical Formula 4: 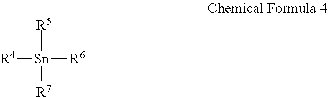
wherein, in Chemical Formula 4,
R⁴ is selected from a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, and L^{a}-O—R^{a} (wherein L^{a} is a substituted or unsubstituted C1 to C20 alkylene group and R^{a} is a substituted or unsubstituted C1 to C20 alkyl group),
R⁵ to R⁷ are each independently —OR^{b} or —OC(═O)R^{c},
R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof, and
R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a combination thereof.

11. The semiconductor photoresist composition as claimed in claim 10, wherein:
R⁴ is a substituted or unsubstituted C1 to C8 alkyl group, a substituted or unsubstituted C3 to C8 cycloalkyl group, a substituted or unsubstituted C2 to C8 aliphatic unsaturated organic group comprising one or more double bonds or triple bonds, a substituted or unsubstituted C6 to C20 aryl group, a substituted or unsubstituted C4 to C20 heteroaryl group, a carbonyl group, ethoxy group, propoxy group, or a combination thereof,
R^{a} is a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof, and
R^{b} is hydrogen, a substituted or unsubstituted C1 to C8 alkyl group, a substituted or unsubstituted C3 to C8 cycloalkyl group, a substituted or unsubstituted C2 to C8 alkenyl group, a substituted or unsubstituted C2 to C8 alkynyl group, a substituted or unsubstituted C6 to C20 aryl group, or a combination thereof.

12. The semiconductor photoresist composition as claimed in claim 10, wherein:
R⁴ is a methyl group, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, a formyl group, an acetyl group, a propanoyl group, a butanoyl group, a pentanoyl group, an ethoxy group, a propoxy group, or a combination thereof,
R^{a} is an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a combination thereof, and
R^{b} is hydrogen, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a combination thereof.

13. The semiconductor photoresist composition as claimed in claim 1, wherein:
the organometallic compound and vinyl group-containing acid compound are included in a weight ratio of about 99:1 to about 80:20.

14. The semiconductor photoresist composition as claimed in claim 1, wherein:
the semiconductor photoresist composition further comprises an additive comprising a surfactant, a crosslinking agent, a leveling agent, organic acid, a quencher, or a combination thereof.

15. A method of forming patterns, comprising:
forming an etching-objective layer on a substrate;
coating the semiconductor photoresist composition as claimed in claim 1 on the etching-objective layer to form a photoresist layer;
patterning the photoresist layer to form a photoresist pattern; and
etching the etching-objective layer using the photoresist pattern as an etching mask.

16. The method of claim 15, wherein the photoresist pattern is formed using light having a wavelength of about 5 nm to about 150 nm.

17. The method of claim 15, wherein:
the method further comprises providing a resist underlayer formed between the substrate and the photoresist layer.

18. The method of claim 15, wherein:
the photoresist pattern has a width of about 5 nm to about 100 nm.
